(19) United States
(12) Patent Application Publication
(10) Pub. No.: US 2015/0213876 A1
(43) Pub. Date: Jul. 30, 2015

(54) SEMICONDUCTOR DEVICE WITH FLOATING BODY STRUCTURE

(71) Applicant: PS4 Luxco S.a.r.l., Luxembourg (LU)

(72) Inventors: Noriaki Mochida, Tokyo (JP); Yasuhiro Matsumoto, Tokyo (JP); Izumi Nakai, Tokyo (JP)

(21) Appl. No.: 14/421,965

(22) PCT Filed: Aug. 19, 2013
(86) PCT No.: PCT/JP2013/004898

§ 371 Date: Feb. 16, 2015

(30) Foreign Application Priority Data
Aug. 17, 2012 (JP) 2012-181041

(51) Int. Cl. G11C 11/4091; H01L 27/092; H01L 29/78; H01L 27/108; G11C 11/4094; G11C 11/408

(52) U.S. Cl. CPC G11C 11/4091; G11C 11/4094; G11C 11/4085; H01L 29/7841; H01L 27/10897; H01L 27/092

(57) ABSTRACT

A semiconductor device is disclosed, which comprises: a memory cell, first and second bit lines, a switch between the first and second bit lines, a sense amplifier, a sense amplifier driving circuit driving the sense amplifier with first and second voltages, a precharge circuit precharging the first bit line, and a control circuit. The control circuit performs a read operation so that the first and second bit lines are disconnected from each other and the first bit line is precharged to a precharge voltage, during a first period. Thereafter, the control circuit performs a restoring operation in a state where the first and second bit lines are connected to each other and the precharging of the first bit line is cancelled, during a second period after the first period. The sense amplifier is driven with the second voltage for increasing its driving ability during the second period

### TECHNICAL FIELD

The present invention relates to a semiconductor device employing memory cells each including a selection transistor with a floating body structure.

### BACKGROUND ART

In recent years, transistor structures for achieving higher integration of memory cells in semiconductor devices such as DRAM (Dynamic Random Access Memory) have become known. For example, a floating body transistor using SOI (Silicon on Insulator) structure has been known as one of such transistor structures. The floating body transistor operates in a state where its body between the source and drain that is disposed over an SOI substrate via an insulating film is fully depleted and electrically floated (for example, see PTL 1). Meanwhile, when the floating body transistor is used to form a memory cell, it is necessary to take measures to prevent stored charge in a capacitor of the memory cell from being lost due to influence of leak current that tends to flow between the source and drain in the floating body because of its structure. For example, a control method is proposed in the PTL 1 (see FIG. 11), in which after a potential of a bit line is sensed and amplified, its amplified state is maintained in a sense amplifier, and a complementary bit line is disconnected from the sense amplifier and is precharged to a predetermined voltage. Thereby, it is possible to suppress the influence of the leak current that flows from a memory cell storing data “High” to a memory cell storing data “Low” through the bit line.

### CITATION LIST

### Patent Literature

PTL 1: Japanese Patent Application Laid-open No. 2011-146104

### SUMMARY OF INVENTION

### Technical Problem

In general, when a read operation of a memory cell is performed in the DRAM, read data needs to be restored into the memory cell. However, if the bit line is maintained in a precharged state as in the above control method, it becomes a problem that a restoring operation of the memory cell cannot be performed. A control in this case may include steps of waiting for issuance of a precharge command after the read operation, performing the restoring operation of the memory cell at this point, and transitioning to a normal precharge operation after the restoring operation. However, this control requires an operation to precharge the bit line again after restoring the data into the memory cell through the bit line. It takes considerable time to perform this operation. Thereby, even if the leak current is suppressed in the DRAM employing memory cells of the floating body type, there is a problem that it becomes difficult to achieve high-speed specification of the DRAM.

### Solution to Problem

One of aspects of the invention is a semiconductor device comprising: a memory cell including a capacitor storing data as electric charge and a selection transistor; a first bit line coupled to the memory cell; a second bit line arranged corresponding to the first bit line; a switch controlling an electrical connection between the first and second bit lines; a sense amplifier amplifying and storing a potential of the second bit line; a sense amplifier driving circuit selectively supplying a first voltage and a second voltage that allows driving ability of the sense amplifier to be higher than the first voltage; a precharge circuit precharging the first bit line to a predetermined precharge voltage; and a control circuit performing a read operation of the memory cell so that the first bit line is disconnected from the second bit line by the switch and the first bit line is precharged to the precharge voltage, during a first period when the sense amplifier stores a potential corresponding to data read out from the memory cell, and performing a restoring operation of the memory cell in a state in which the first bit line is connected to the second bit line via the switch and the precharging of the first bit line is cancelled, during a second period after the first period, wherein the control circuit controls the sense amplifier driving circuit to drive the sense amplifier with at least the second voltage during the second period.

According to the semiconductor device of an embodiment, when performing the read operation of the memory cell, during the first period when the sense amplifier stores read data, influence of leak current of the floating body type selection transistor is suppressed by precharging the first bit line to the precharge voltage with the switch being disconnected, and during the subsequent second period, the precharging of the first bit line is cancelled and the restoring operation of the memory cell is performed via the switch. At this point, since the potential supplied to the sense amplifier during the second period is controlled to transition from the second voltage to the first voltage, driving ability of the sense amplifier is increased so that its potential rapidly changes, thereby shortening a time required for the restoring operation of the memory cell. In particular, the invention can be effectively applied to a semiconductor device comprising a hierarchical bit line structure including a local bit line and a global bit line.

### Advantageous Effects of Invention

As describe above, according to the present invention, in a semiconductor device having memory cells of a floating body type, even when performing a control to suppress influence of leak current after a read operation of a memory cell, this control does not allow restoring time of the memory cell from being prolonged, and a restoring operation of the memory cell can be rapidly performed, thereby achieving a semi-conductor device capable of operating in high speed.

### BRIEF DESCRIPTION OF DRAWINGS

FIG. 1 is a block diagram showing an entire configuration of DRAM of a first embodiment.

FIG. 2 is a diagram showing an example of a partial circuit configuration of a memory cell array of FIG. 1.

FIG. 3 is a diagram showing an example of a schematic cross-sectional structure of a memory cell of a floating body type.

FIG. 4 is a diagram showing a configuration of a sense amplifier and a sense amplifier driving circuit.

FIG. 5 is a diagram showing a comparison example of operation waveforms obtained when an overdriving operation of the sense amplifier is not performed during a restoring operation after a read operation of the DRAM of the first embodiment.

FIG. 6 is a diagram showing operation waveforms obtained by a control of the first embodiment in relation to the read operation of the first embodiment.

FIG. 7 is a diagram showing operation waveforms obtained when performing a read operation of a memory cell in DRAM of a second embodiment.

FIG. 8 is a diagram showing operation waveforms obtained when performing a write operation of the memory cell in the DRAM of the second embodiment.

### DESCRIPTION OF EMBODIMENTS

Preferred embodiments of the present invention will be described in detail below with reference to accompanying drawings. In the following embodiments, the present invention will be applied to DRAM (Dynamic Random Access Memory) as an example of a semiconductor device.

### First Embodiment

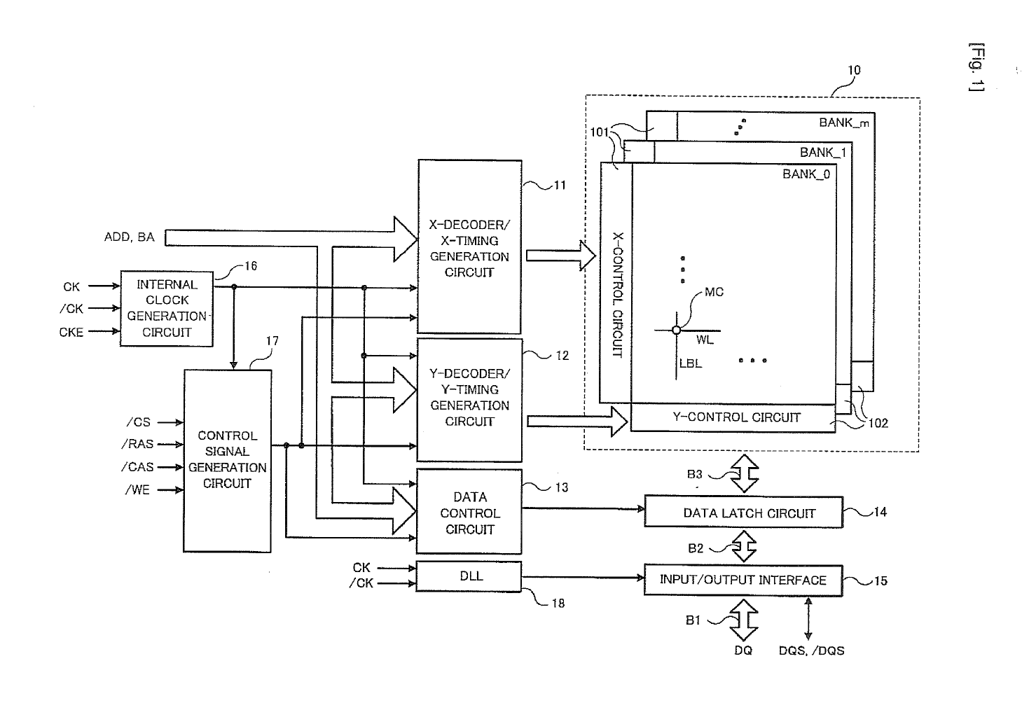

A configuration and an operation of DRAM of a first embodiment of the present invention will be described below. FIG. 1 is a block diagram showing an entire configuration of the DRAM of the first embodiment. The DRAM shown in FIG. 1 includes a memory cell array 10, an X-decoder/X-timing generation circuit 11, a Y-decoder/Y-timing generation circuit 12, a data control circuit 13, a data latch circuit 14, an input/output interface 15, an internal clock generation circuit 16, a control signal generation circuit 17, and a DLL (Delay Locked Loop) circuit 18.

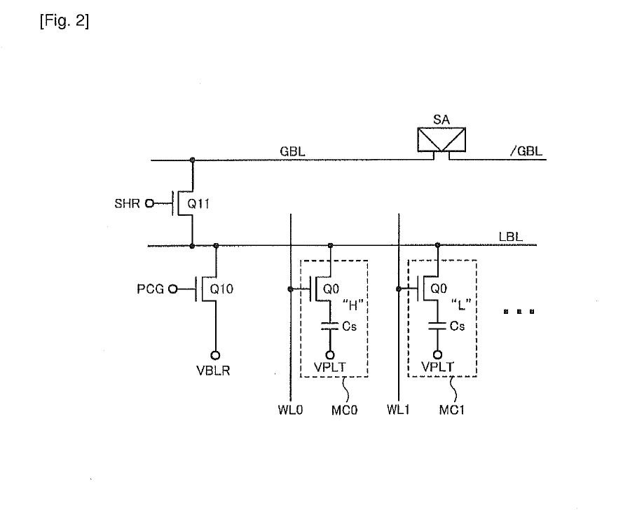

The memory cell array 10 includes a plurality of memory cells MC formed at intersections of a plurality of word lines WL and a plurality of local bit lines LBL. It is assumed that the plurality of memory cells MC employ a floating body structure, which will be described in detail later. Further, the memory cell array 10 has a hierarchical bit line structure including the local bit lines LBL of a lower layer and global bit lines GBL (FIG. 2) of an upper layer. The memory cell array 10 is divided into a plurality of memory banks (BANK), each of which is independently controllable. In the example of FIG. 1, m+1 (m is an integer) memory banks (BANK_0 to BANK_m) are provided. Each bank is provided with an X-control circuit 101 and a Y-control circuit 102. Further, around each bank, there are sense amplifiers as described later, and sub-word drivers that drive the word lines WL.

The memory cell array 10 is connected to the data latch circuit 14 via a bus B3 for data transfer. The data latch circuit 14 is connected to the input/output interface 15 via a bus B2 for data transfer. The input/output interface 15 inputs/outputs data (DQ) and data strobe signals DQS and /DQS from/to outside via a bus B1 for data transfer. The data transfer through the buses B1, B2 and B3 is controlled by the data control circuit 13, and output timings of the input/output interface 15 are controlled by the DLL circuit 18 to which external clock signals CK and /CK are supplied. Further, the X-decoder/X-timing generation circuit 11 controls the X-control circuit 101 of each bank, and the Y-decoder/Y-timing generation circuit 12 controls the Y-control circuit 102 of each bank.

The internal clock generation circuit 16 generates internal clocks based on the external clock signals CK and /CK and a clock enable signal CKE, and supplies them to various parts of the DRAM. The control signal generation circuit 17 generates control signals based on a chip select signal /CS, a row address strobe signal /RAS, a column address strobe signal /CAS, and a write enable signal /WE that are received from outside, and supplies them to various parts of the DRAM. In addition, an address ADD and a bank address BA are supplied from outside to the X-decoder/X-timing generation circuit 11, the Y-decoder/Y-timing generation circuit 12 and the data control circuit 13.

Next, a configuration and an operation of a major part of the memory cell array 10 of

FIG. 1 in the DRAM of the first embodiment will be described. FIG. 2 shows an example of a partial circuit configuration of the memory cell array 10 of FIG. 1. The circuit configuration of FIG. 2 corresponds to a range including one local bit line LBL and adjacent two memory cells MC0 and MC1 coupled to the local bit line LBL, and peripheral circuits. One memory cell MC0 is formed at an intersection of a word line WL0 and the local bit line LBL, and the other memory cell MC1 is formed at an intersection of a word line WL1 and the local bit line LBL. Although FIG. 2 shows only two memory cells MC0 and MC1, a predetermined number of memory cells MC are practically coupled to each one of the local bit lines LBL, and there are arranged the same number of the word lines WL as the memory cells MC.

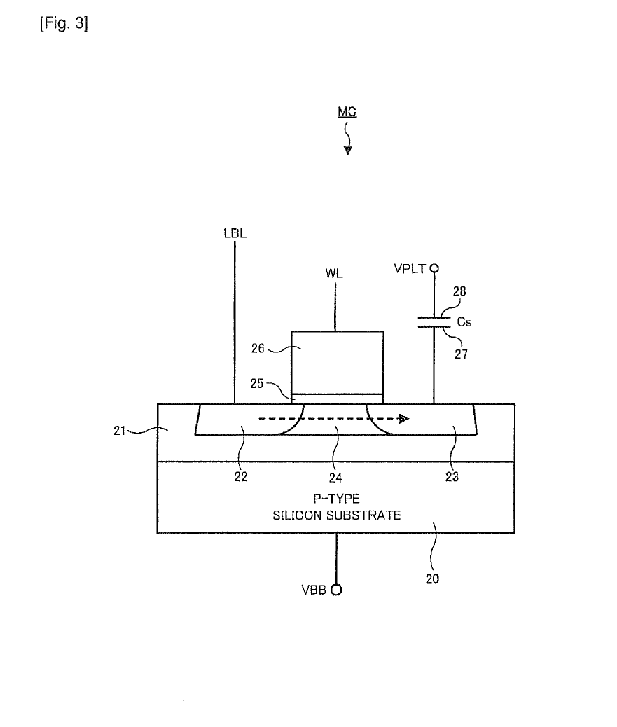

Each of the memory cells MC (including memory cells MC0 and MC1) is formed by series-connecting a floating body type selection transistor (Hereinafter, referred to simply as “selection transistor”) Q0, and a capacitor Cs that stores binary data (“High” or “Low”) as electric charge. FIG. 3 shows an example of a schematic cross-sectional structure of a memory cell MC of the floating body type. In the example shown in FIG. 3, a P-type silicon substrate 20 is applied with a substrate voltage VBB, and an element isolation insulating film 21 is formed thereon. A transistor structure of the selection transistor Q0 is formed on the element isolation insulating film 21, which includes an N-type impurity layer 22 as a source, an N-type impurity layer 23 as a drain, and a floating body 24 operating in a full depletion state between the source and drain. One N-type impurity layer 22 is connected to a local bit line LBL on an upper layer, and the other N-type impurity layer 23 is connected to a storage electrode 27 as one electrode of the capacitor Cs. A plate electrode 28 as the other electrode of the capacitor Cs faces the storage electrode 27 via a dielectric film, and is connected to a line of a plate voltage VPLT on an upper layer. Further, a gate electrode 26 connected to the word line WL is formed over the floating body 24 between the N-type impurity layers 22 and 23 via a gate dielectric film 25.

A structural feature of the select transistor shown in FIG. 3 is that regions of the select transistor Q0 including the source and drain (the N-type impurity layers 22 and 23) and the floating body 24 are separated from the P-type silicon substrate 20 via the element isolation insulating film 21. By this structure, the floating body 24 is in a floating state. A silicon layer having the N-type impurity layers 22, 23 and the floating body 24 on the element isolation insulating film 21 is formed, for example, with a thickness smaller than 50 mm, without being limited thereto. In this case, the floating body 24 acts in a fully depleted state, and a neutral region of P-type silicon does not exist therein. Here, a leak current tends to flow between the source and drain in the floating body structure shown in FIG. 3, and thus it is necessary to take measures to prevent stored charge in the capacitor Cs of the memory cell MC from being lost due to the leak current, which will be described in detail later.

Returning to FIG. 2, a transistor Q10 has a function to precharge the local bit line LBL to a precharge voltage VBLR in response to a precharge signal PCG applied to its gate. The precharge voltage VBLR is set to, for example, an intermediate voltage between a power supply voltage and a ground potential. By setting the precharge signal PCG to a “High” level, the local bit line LBL can be precharged to the precharge voltage VBLR. In the first embodiment, the local bit line LBL is precharged to the precharge voltage VBLR not only during a precharge operation, but also during a predetermined period after an active operation.

A transistor Q11 is a hierarchical switch that controls a connection state between the local bit line LBL and the global bit line GBL in response to a control signal SHR applied to its gate. When the control signal SHR is set to “High”, the local bit line LBL and the global bit line GBL are electrically connected to each other, and when the control signal SHR is set to “Low”, the local bit line LBL and the global bit line GBL are electrically disconnected from each other.

In addition, the precharge signal PCG and the control signal SHR are generated by the X-decoder/X-timing generation circuit 11 of FIG. 1.

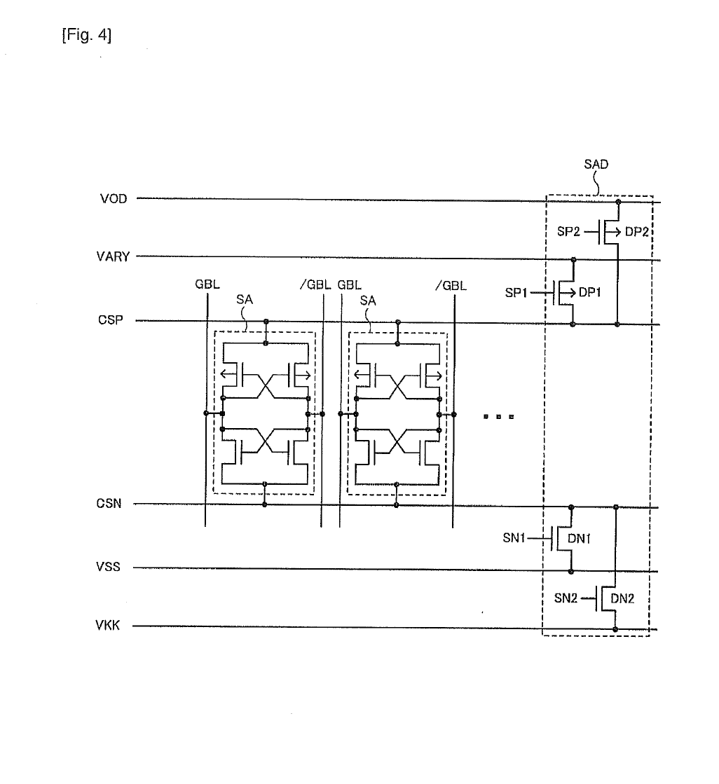

A sense amplifier SA is connected to one end of the global bit line GBL. The sense amplifier SA is connected to the global bit line GBL and a global bit line /GBL that forms a complementary pair with the global bit line GBL, and has a differential configuration that amplifies and stores a voltage difference between the both lines. In the first embodiment, it is assumed that overdrive technique for supplying two different potentials to the sense amplifier SA is employed. Hereinafter, a configuration of the sense amplifier SA and a sense amplifier driving circuit SAD around the sense amplifier SA will be described referring to FIG. 4. Since potentials from the sense amplifier driving circuit SAD are supplied to a plurality of sense amplifiers SA in common, a circuit portion of FIG. 4 includes the plurality of sense amplifiers SA.

As shown in FIG. 4, each of the sense amplifiers SA includes a pair of inverters composed of two PMOS transistors and two NMOS transistors, in which inputs and outputs of the inverters are cross-coupled to each other. A pair of global bit lines GBL and /GBL are connected to two input nodes of the sense amplifier SA. In the upper and lower parts of FIG. 4, there are arranged a common source line CSP for supplying a high-voltage power supply to the two PMOS transistors in the sense amplifier SA, and a common source line CSN for supplying a low-voltage power supply to the two NMOS transistors in the sense amplifier SA. Two PMOS transistors functioning as a driver DP1 for normal operation and a driver DP2 for overdriving are provided at one end of the common source line CSP for PMOS, and two NMOS transistors functioning as a driver DN1 for normal operation and a driver DN2 for overdriving are provided at one end of the common source line CSN for NMOS.

In the side of the common source line CSP for PMOS, the driver DP1 for normal operation supplies an array voltage VARY to the common source line CSP in response to a control signal SP1 applied to its gate, and the driver DP2 for overdriving supplies an overdrive voltage VOD higher than the array voltage VARY to the common source line CSP in response to a control signal SP2 applied to its gate. Further, in the side of the common source line CSN for NMOS, the driver DN1 for normal operation supplies a ground potential VSS to the common source line CSN in response to a control signal SN1 applied to its gate, and the driver DN2 for overdriving supplies a negative voltage VKK lower than the ground potential VSS to the common source line CSN in response to a control signal SN2 applied to its gate. By this configuration, the sense amplifier SA is driven by the array voltage VARY and the ground potential VSS in the normal operation of the sense amplifier SA, while the sense amplifier SA is driven by the overdrive voltage VOD and the negative voltage VKK in an overdriving operation of the sense amplifier SA so that driving ability of the sense amplifier SA is increased.

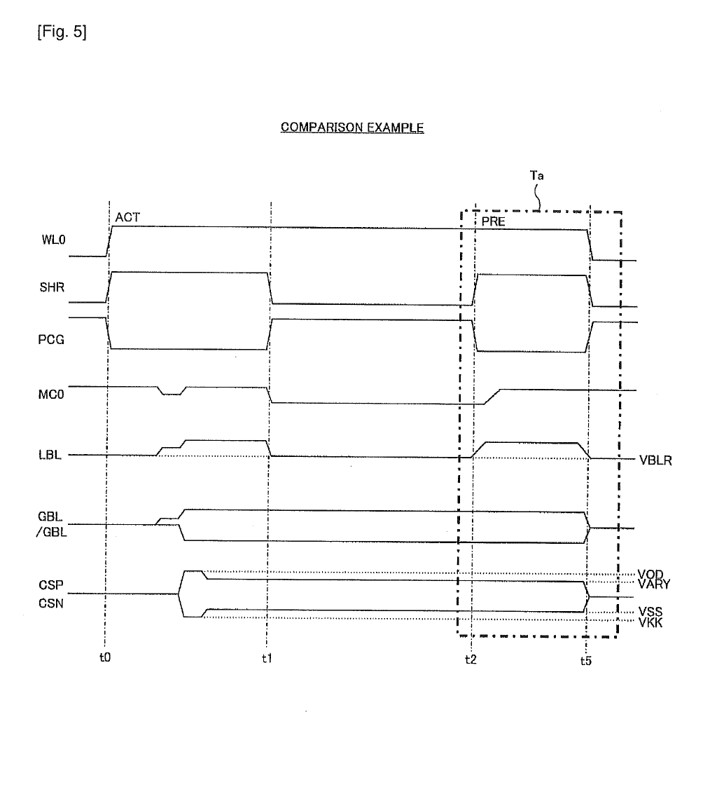

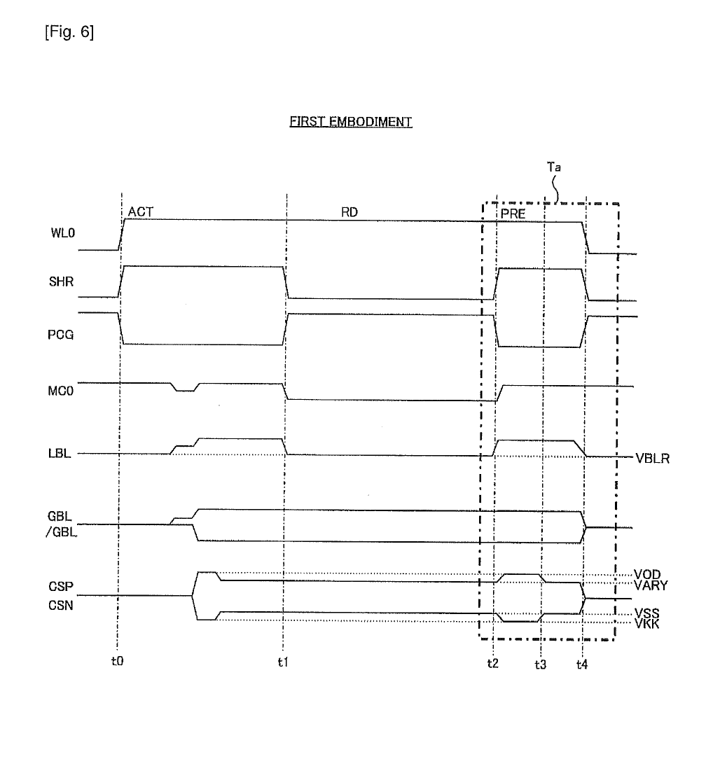

Next, a read operation of the DRAM of the first embodiment will be described. The first embodiment is characterized in that an overdriving operation of the sense amplifier SA is performed during a restoring operation after the read operation. In order to compare with the first embodiment, FIG. 5 shows a comparison example of operation waveforms obtained when the overdriving operation of the sense amplifier SA is not performed during the restoring operation, and FIG. 6 shows operation waveforms obtained by the control of the first embodiment. FIGS. 5 and 6 correspond to operation waveforms obtained when reading out data stored in the memory cell MC0 in the configuration of FIG. 2, in a situation where one memory cell MC0 stores data “High” while the other memory cell MC1 stores data “Low”. Thus, since the operation waveforms of FIGS. 5 and 6 are common to each other except operation waveforms during a period of time Ta in the second half of FIGS. 5 and 6, the following descriptions leading to the period of time Ta are common to both FIGS. 5 and 6.

The local bit line LBL and the global bit line GBL have been precharged at an early point of FIGS. 5 and 6. Further, the transistor Q11 as the hierarchical switch is kept OFF, and the local bit line LBL and the global bit line GBL have been disconnected from each other. Thereafter, when an active command ACT is issued at a timing t0, the read operation of the memory cell MC0 is started. At this point, the precharge signal PCG is set to “Low” so that the precharging of the local bit line LBL is cancelled, and the control signal SHR is set to “High” so that the local bit line LBL and the global bit line GBL are connected to each other via the transistor Q11. Further, the word line WL0 is driven into a selected state (“High”). Thereby, a minute potential is read out from the memory cell MC0 storing the data “High” to the local bit line LBL, and the potential is transmitted to the global bit line GBL via the transistor Q11. In addition, the precharging of the global bit line GBL has been also cancelled at this point.

Subsequently, the sense amplifier SA is driven. That is, a pair of drivers DP2 and DN2 for overdriving is activated in the sense amplifier driving circuit SAD (FIG. 4), and the overdrive voltage VOD and the negative voltage VKK are supplied from a pair of common source lines CSP and CSN to the sense amplifier SA. Then, after a predetermined time is elapsed, the state of the sense amplifier driving circuit SAD is switched so that a pair of drivers DP1 and DN1 for normal operation is activated, and the power supply sources for the sense amplifier SA are changed to the array voltage VARY and the ground potential VSS.

Thereafter, in the first embodiment, a control of measures against the leak current in the memory cell MC of the floating body type is started after a timing t1. Specifically, by setting the precharge signal PCG to “High” and setting the control signal SHR to “Low” at the timing t1, respectively, the local bit line LBL is precharged to the precharge voltage VBLR in a state of being disconnected from the global bit line GBL. At this point, since the word line WL0 is maintained in the selected state, the potential of the memory cell MC0 to be read drops to the precharge voltage VBLR. However, the global bit line GBL continues to be maintained at the potential that is sensed and amplified by the sense amplifier SA. Since the potential of the local bit line LBL transitions to a level of the precharge voltage VBLR, it is possible to suppress the leak current of the memory cell MC1 that is connected to the local bit line LBL in common with the memory cell MC0, thereby preventing the data “Low” stored in the memory cell MC1 from being lost.

Meanwhile, the restoring operation of the first embodiment is not performed when the active command ACT is issued, and is performed when a precharge command PRE is issued after the above measures taken against the leak current. As described above, during the period of time Ta associated with the precharge command PRE, different controls are performed in the comparison example of FIG. 5 and in the first embodiment of FIG. 6. First, in FIGS. 5 and 6, by setting the precharge signal PCG to “Low” and setting the control signal SHR to “High”, respectively, at a timing t2 after transitioning to the period of time Ta, the local bit line LBL and the global bit line GBL are connected to each other, while cancelling the precharging of the local bit line LBL. At this point, potentials of the pair of common source lines CSP and CSN connected to the sense amplifier SA continue to be maintained at the array voltage VARY and the ground potential VSS, as shown in FIG. 5. Thus, the potential of the local bit line LBL rises relatively gradually in response to driving ability of the sense amplifier SA in the normal operation. Along with this, the data “High” is restored into the memory cell MC0, and the sense amplifier SA is deactivated at a subsequent timing t5.

On the other hand, in FIG. 6, the potentials of the pair of common source lines CSP and CSN change to the overdrive voltage VOD and the negative voltage VKK at the timing t2. Thus, the driving ability of the sense amplifier SA increases, and the potential of the local bit line LBL rapidly rises compared to FIG. 5. Along with this, the data “High” is restored into the memory cell MC0 within a shorter time than the case of FIG. 5. Then, the potentials of the pair of common source lines CSP and CSN are returned to the array voltage VARY and the ground potential VSS again at a timing t3 when a predetermined time is elapsed, and the sense amplifier SA returns to the normal driving ability. Further, the sense amplifier SA is deactivated at a subsequent timing t4. In addition, the timings t3 and t4 of FIG. 6 precede the timing t5 of FIG. 5.

FIG. 6 shows a case in which, during the period of time Ta, the potentials of the pair of common source lines CSP and CSN are changed from the array voltage VARY and the ground potential VSS to the overdrive voltage VOD and the negative voltage VKK once, and thereafter they are returned to the array voltage VARY and the ground potential VSS again. However, the above overdriving can be applied without being limited to such case. For example, there is a method as a modification of FIG. 6, in which the overdrive voltage VOD and the negative voltage VKK continue to be applied to the sense amplifier SA during a sensing period. That is, it is possible to employ a control method in which, when driving the sense amplifier SA during a period between the timings t0 to t1, the potentials of the pair of common source lines CSP and CSN are changed to the overdrive voltage VOD and the negative voltage VKK first, and thereafter while maintaining this state, the sense amplifier SA is deactivated without transitioning to the array voltage VARY and the ground potential VSS during the period of time Ta.

States during the period of time Ta of FIGS. 5 and 6 both become the same as at the early point after the restoring operation of the memory cell MC0 is completed. That is, the word line WL0 is set to a non-selected state (“Low”) after the local bit line LBL and the global bit line GBL are precharged, and the local bit line LBL and the global bit line GBL are disconnected from each other by the transistor Q11. In this state, it is controlled so as to wait for issuance of a subsequent active command ACT.

By employing the control of the first embodiment, during the period of time Ta after the measures taken against the leak current, it is possible to shorten a restoring time when restoring the data “High” into the memory cell MC0 before the precharge operation. That is, by increasing the driving ability of the sense amplifier SA in the restoring operation, the potential of the local bit line LBL can be rapidly changed, and in tandem with this, the potential of the memory cell MC0 can be also rapidly changed. Here, the period tRP specified for DRAM means a time required from issuance of a precharge command PRE to issuance of a subsequent active command ACT. Due to the control of FIG. 5, a restoring time longer than that of FIG. 6 of the first embodiment is required, and therefore the issuance of the subsequent active command ACT is correspondingly delayed, which makes it difficult to achieve a desired period tRP. In contrast, by employing the control of the first embodiment, it is possible to shorten the restoring time so that the desired period tRP can be easily achieved.

In order to evaluate effects of the first embodiment, respective restoring times of FIGS. 5 and 6 are obtained by simulation. As a result, it is confirmed that a restoring time of about 6 ns is obtained in the case of FIG. 5 and a restoring time of about 3 ns is obtained in the case of FIG. 6, under a common circuit condition that is practically assumed. That is, it is confirmed that the restoring time can be reduced to approximately half by employing the control of the first embodiment that includes the overdriving operation of the sense amplifier SA.

### Second Embodiment

A configuration and an operation of DRAM of a second embodiment of the present invention will be described below. In the second embodiment, all of the entire configuration of the DRAM in FIG. 1, the partial circuit configuration of the memory cell array 10 in FIG. 2, the schematic cross-sectional structure of the memory cell MC in FIG. 3, and the configuration of the sense amplifier SA and the sense amplifier driving circuit SAD in FIG. 4 are common to those of the first embodiment, so descriptions thereof will be omitted.

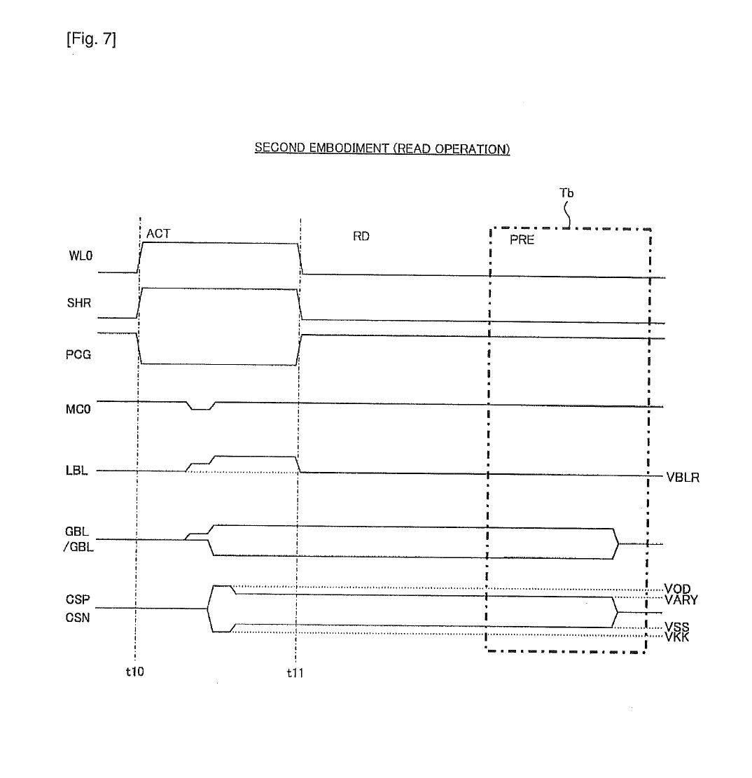

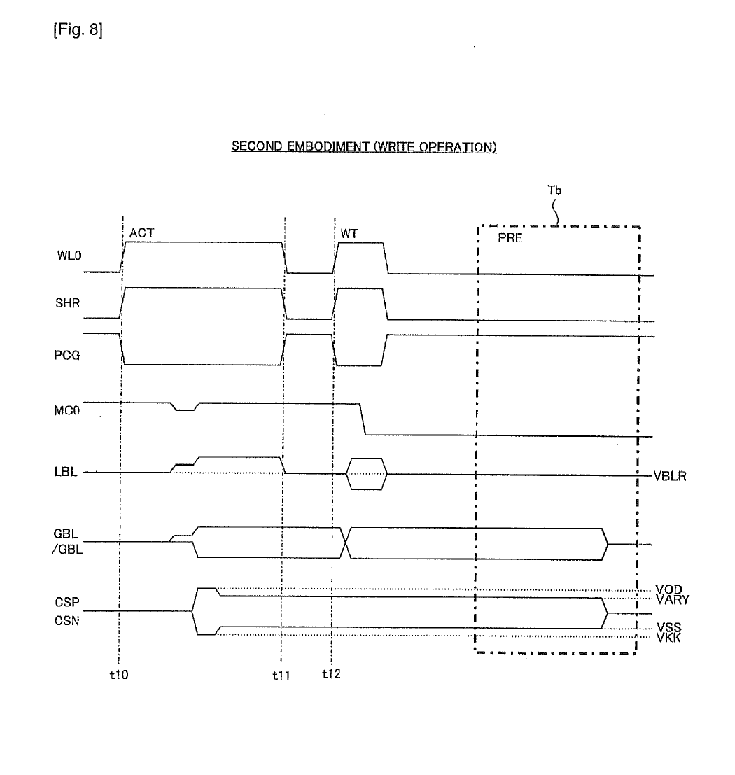

Next, controls of the DRAM of the second embodiment will be described. In the configuration of FIG. 2, the situation is the same as the first embodiment, in which one memory cell MC0 stores the data “High” while the other memory cell MC1 stores the data “Low”. In the second embodiment, FIG. 7 shows an example of operation waveforms obtained when performing a read operation of the memory cell MC0, and FIG. 8 shows an example of operation waveforms obtained when performing a write operation of the memory cell MC0.

First, in the read operation of FIG. 7, the state at an early point is the same as that in FIG. 6 of the first embodiment. Further, the operation waveforms from a timing t10 when an active command ACT is issued to a timing t11 are the same as those in FIG. 6 of the first embodiment. Meanwhile, in FIG. 7, the word line WL0 is set to a non-selected state at the timing t11, as different from FIG. 6. Further, by setting the precharge signal PCG to “High” and setting the control signal SHR to “Low”, respectively, the local bit line LBL is precharged to the precharge voltage VBLR in a state of being disconnected from the global bit line GBL. Meanwhile, the sense amplifier SA and the global bit line GBL continue to keep their previous states after the timing t11.

Thereafter, when a read command RD is issued at a predetermined timing, the data stored in the sense amplifier SA is transmitted to the Y-control circuit 102 (FIG. 1). At this point, the operation waveforms shown in FIG. 7 are maintained in their states. Thereafter, a precharge command PRE is issued when transitioning to a period of time Tb, and the global bit line GBL and the common source lines CSP and CSN are precharged.

Next, in the write operation of FIG. 8, the operation waveforms from the early point to a timing t12 through the timings t10 and t11 are the same as those in the read operation of FIG. 7. Meanwhile, when a write command WR is issued at the timing t12, the precharge signal PCG is set to “Low” so that the precharging of the local bit line LBL is cancelled, and the control signal SHR is set to “High” so that the local bit line LBL and the global bit line GBL are connected to each other. At this point, data from the Y-control circuit 102 is transmitted from the sense amplifier SA through the global bit line GBL, the transistor Q11 and the local bit line LBL. In this case, since the word line WL0 is in a selected state, the above data is written into the memory cell MC0. Here, FIG. 8 shows a case where the data “Low” is written into the memory cell MC0.

When the write operation of the memory cell MC0 is completed, each of the precharge signal PCG, the control signal SHR and the word line WL0 returns to the same state as at the early point. Thereby, the local bit line LBL is precharged to the precharge voltage VBLR, and subsequent operation waveforms are the same as those in FIG. 7 including the period of time Tb. Here, by comparing the operation waveforms in FIGS. 7 and 8 with the operation waveforms in FIG. 6 of the first embodiment, it can be found that the restoring operation during the period of time Ta in the first embodiment does not need to be performed during the period of time Tb in the second embodiment.

By employing the control of the second embodiment, the restoring operation before the precharge operation becomes unnecessary after the measures taken against the leak current, as different from the first embodiment. That is, the state of the memory cell MC0 is maintained if the read command RD is issued, and data is written into the memory cell MC0 via the hierarchical switch at this timing if the write command WT is issued. Therefore, in both cases, the restoring operation of the memory cell MC0 is unnecessary before the precharge operation. Thus, it is possible to perform the subsequent precharge operation within a short time.

In the foregoing, the preferred embodiments of the present invention has been described. However, the present invention is not limited to the above embodiments, and can variously be modified without departing the essentials of the present invention. For example, the present invention can be applied to various semiconductor devices such as CPU (Central Processing Unit), MCU (Micro Control Unit), DSP (Digital Signal Processor), ASIC (Application Specific Integrated Circuit), ASSP (Application Specific Standard Product) and the like, without being limited to the DRAM as the semiconductor device.

This description is based on Japanese Patent Application No. 2012-181041 filed on Aug. 17, 2012, and all contents of the application are included herein.

### INDUSTRIAL APPLICABILITY

As described above, the present invention is applied to a semiconductor memory device employing memory cells each including a selection transistor with a floating body structure, and is suitable to shorten restoring time when performing a restoring operation of a memory cell.

### REFERENCE SIGNS LIST

10: memory cell array

11: X-decoder/X-timing-generation-circuit

12: Y-decoder/Y-timing-generation-circuit

13: data control circuit

14: data latch circuit

15: input/output interface

16: internal clock generation circuit

17: control signal generation circuit

18: DLL circuit

20: p-type silicon substrate

21: element isolation insulating film

22, 23: n-type impurity layer

24: floating body

25: gate dielectric film

26: gate electrode

27: storage electrode

28: plate electrode

MC: memory cell

WL: word line

LBL: local bit line

GBL and /GBL: global bit line

SA: sense amplifier

SAD: sense amplifier driving circuit

DP1 and DN1: driver for normal operation

DP2 and DN2: driver for overdriving

Q10 and Q11: transistor

CSP and CSN: common source line

SHR: control signal

PCG: precharge signal

VBLR: precharge voltage

VOD: overdrive voltage

VARY: array voltage

VSS: ground potential

VKK: negative voltage

1. A semiconductor device comprising:
a memory cell including a capacitor storing data as electric charge and a selection transistor;
a first bit line coupled to the memory cell;
a second bit line arranged corresponding to the first bit line;
a switch controlling an electrical connection between the first and second bit lines;
a sense amplifier amplifying and storing a potential of the second bit line;
a sense amplifier driving circuit selectively supplying a first voltage and a second voltage that allows driving ability of the sense amplifier to be higher than the first voltage;
a precharge circuit precharging the first bit line to a predetermined precharge voltage; and
a control circuit performing a read operation of the memory cell so that the first bit line is disconnected from the second bit line by the switch and the first bit line is precharged to the precharge voltage, during a first period when the sense amplifier stores a potential corresponding to data read out from the memory cell, and performing a restoring operation of the memory cell in a state in which the first bit line is connected to the second bit line via the switch and the precharging of the first bit line is cancelled, during a second period after the first period,
wherein the control circuit controls the sense amplifier driving circuit to drive the sense amplifier with at least the second voltage during the second period.

2. The semiconductor device according to claim 1, wherein the control circuit controls the sense amplifier driving circuit to drive the sense amplifier with the first voltage after driving it with the second voltage during the second period.

3. The semiconductor device according to claim 1, further comprising a hierarchical bit line structure including a local bit line and a global bit line,
wherein the first bit line is the local bit line and the second bit line is the global bit line.

4. The semiconductor device according to claim 3, wherein the sense amplifier has a differential configuration to which the global bit line and a complementary global bit line that forms a complementary pair with the global bit line are connected.

5. The semiconductor device according to claim 4, wherein the sense amplifier includes a plurality of PMOS transistors and a plurality of NMOS transistors.

6. The semiconductor device according to claim 5, further comprising:
a first line connected to sources of the plurality of PMOS transistors; and
a second line connected to sources of the plurality of NMOS transistors,
wherein a first positive voltage as the first voltage and a second positive voltage as the second voltage are selectively supplied through the first line,
and a first negative voltage as the first voltage and a second negative voltage as the second voltage are selectively supplied through the second line.

7. The semiconductor device according to claim 1, wherein the precharge voltage is set to an intermediate voltage between a potential corresponding to high level data of the memory cell and a potential corresponding to low level data of the memory cell.

8. The semiconductor device according to claim 1, further comprising a word line selectively connecting the memory cell to the local bit line, wherein the word line corresponding to a selected memory cell is driven into a selected state during the first and second periods.

9. The semiconductor device according to claim 1, wherein the switch includes one or more transistors.

10. The semiconductor device according to claim 1, wherein the selection transistor is a transistor of a floating body type.
